(19) United States
(12) Patent Application Publication
(10) Pub. No.: US 2008/0200037 A1
(43) Pub. Date: Aug. 21, 2008

(54) Method of thinning a wafer

(76) Inventors: Yu-Pin Tsai, Kao-Hsiung City (TW); Cheng-I Huang, Kaohsiung County (TW)

Correspondence Address: NORTH AMERICA INTELLECTUAL PROPERTY CORPORATION, P.O. BOX 506, MERRIFIELD, VA, 22116, US

(21) Appl. No.: 11/953,846

(22) Filed: Dec. 10, 2007

(30) Foreign Application Priority Data
Feb. 16, 2007 (TW) 096105993

(51) Int. Cl. H01L 21/00

(52) U.S. Cl. 438/759; 257/E21.001

(57) ABSTRACT

A method of thinning wafer is disclosed. A wafer has an active surface and a back surface is provided. A plurality of protruding components may be disposed on the active surface. The wafer is placed in a mold and a polymeric material is formed in the mold to cover at least the active surface of the wafer. The polymeric material is cured and the mold is removed. The back surface of the wafer is ground to thin the wafer. The polymeric material is removed to expose the active surface of the wafer and the protruding components disposed on the active surface. The polymeric material is allowed to cover the active surface of the wafer and the protruding components through the mold; accordingly, the stress produced during the grinding can be distributed uniformly on the wafer, and the wafer warpage, breakage, or collapse, or the protruding component peeling can be avoided.

### BACKGROUND OF THE INVENTION

1. Field of the Invention

The present invention relates to a method of thinning a wafer, and particularly to a method of thinning a wafer, by using which damage of the wafer or the protruding components on the wafer is avoided.

2. Description of the Prior Art

In order to thin the semiconductor package, a thinning process is usually performed on the back surface of wafers for thinning the wafers. However, there are usually circuit patterns or various protruding devices, such as bumps or passive components, disposed on the active surface of the wafers. Therefore, when a grinding process is performed on the back surface of the wafer to thin the wafer, the active surface and the protruding components must be protected through covering with an adhesive tape or film. As shown in FIGS. 1 and 2, a conventional wafer 100 has an active surface 110, a back surface 120, and a side surface 130 between the active surface 110 and the back surface 120. A plurality of protruding components 140 are disposed on the active surface 110. An adhesive film 10 covers the active surface 110 of the wafer 100 to protect the active surface 110 and the protruding components 140 when the back surface 120 of the wafer 100 is ground. However, the adhesive film 10 is composed of a substrate 11, an ultra-soft layer 12, and an adhesive layer 13. The adhesive film 10 is expensive and it cannot completely cover the active surface 110 of the wafer 100 and encapsulate the protruding components 140 when the interval spaces among the protruding components 140 are too small. Accordingly, breakage and warpage easily occur due to the stress produced from the grinding of the back surface 120 of the wafer 100. In addition, since the side surface 130 of the wafer 100 is not covered by the adhesive film 10, collapse of the wafer 100 during the grinding tends to occur. Furthermore, when the adhesive film 10 is released, the protruding components 140 disposed on the active surface 110 are peeled by the adhesive film 10. Moreover, if the adhesive film 10 is not removed completely, the residues will reside on the active surface 110, causing contamination.

### SUMMARY OF THE INVENTION

The main objective of the present invention is to provide a method of thinning a wafer. First, a wafer having an active surface and a back surface is provided. A plurality of protruding components may be disposed on the active surface. Next, the wafer is placed in a mold and a polymeric material is filled in the mold. The polymeric material covers at least the active surface of the wafer. Thereafter, the polymeric material is cured and the mold is removed. Thereafter, the back surface of the wafer is ground. Finally, the polymeric material is removed to expose the active surface and the protruding components of the wafer. The mold is utilized to allow the polymeric material to cover the active surface of the wafer and encapsulate the protruding components, such that the stress produced during the wafer is ground can be uniformly distributed on the wafer to prevent the wafer from warpage or breakage.

Another objective of the present invention is to provide a method of thinning a wafer, wherein the polymeric material further covers a side surface of the wafer, accordingly, to prevent the wafer from collapse during the grinding of the back surface of the wafer.

Further another objective of the present invention is to provide a method of thinning a wafer, wherein the polymeric material is a wax, and, in the step of removing the polymeric material, the wafer is rinsed with a hot water to remove the wax layer.

In accordance with the method of thinning a wafer of the present invention, first, a wafer is provided. The wafer has an active surface and a back surface. Next, the wafer is placed in a mold. Thereafter, a polymeric material is formed in the mold. The polymeric material covers at least the active surface of the wafer. Subsequently, the polymeric material is cured and the mold is removed. Thereafter, the back surface of the wafer is ground to thin the wafer. Finally, the polymeric material is removed to expose the active surface.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-section view of a conventional wafer and an adhesive film which attaches the active surface of the wafer;

FIG. 2 is a schematic cross-section view of the conventional wafer which warps after the adhesive film is removed;

FIGS. 3A through 3E are schematic cross-section views showing a first embodiment of the method of thinning a wafer according to the present invention;

FIG. 4 is a schematic cross-section view showing a second embodiment according to the present invention, the wafer is encapsulated in the polymeric material; and

FIG. 5 is a schematic cross-section view showing a third embodiment according to the present invention, the wafer is encapsulated in the polymeric material.

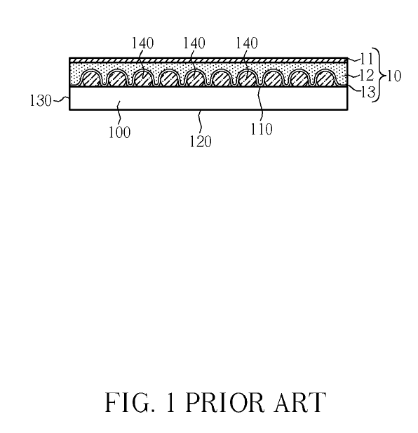

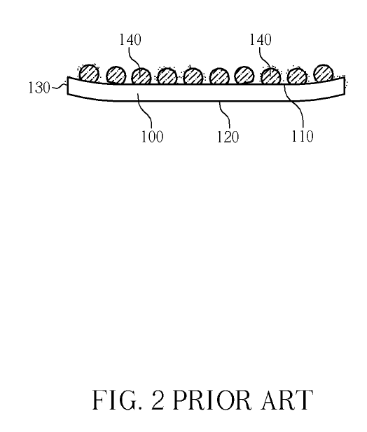

### DETAILED DESCRIPTION

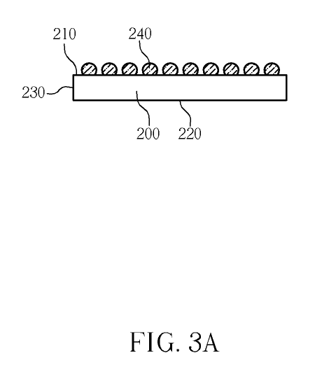

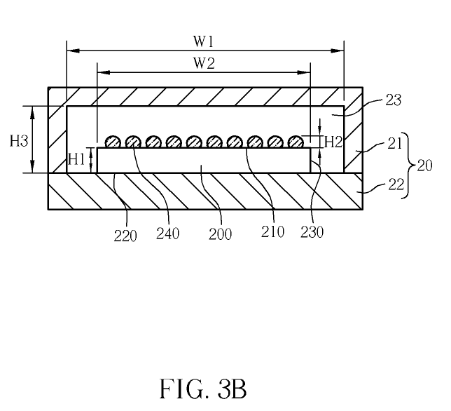

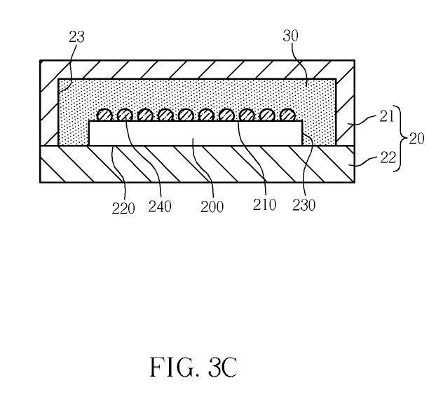

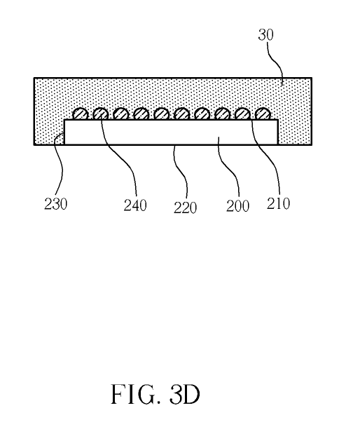

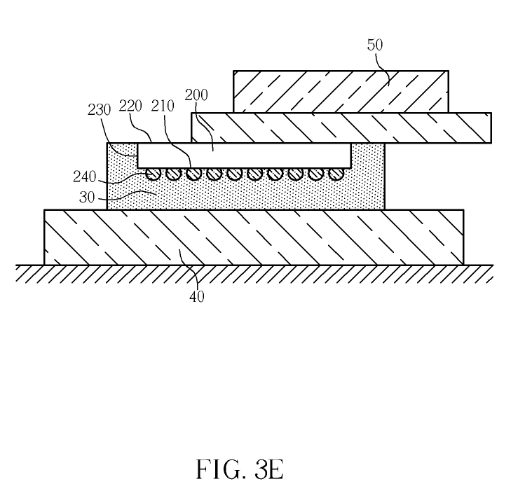

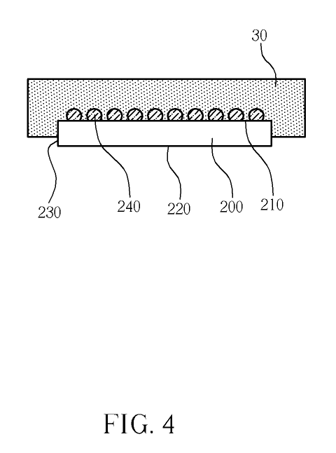

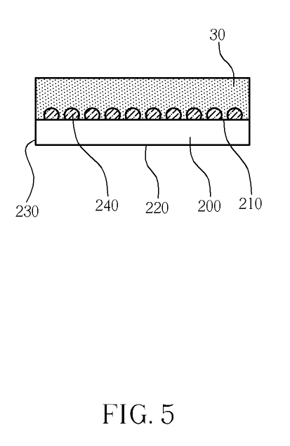

Please refer to FIG. 3A through 3E, illustrating a first embodiment of the method of thinning a wafer according to the present invention. First, referring to FIG. 3A, a wafer 200 is provided. The wafer 200 has an active surface 210, a back surface 220, and at least one side surface 230 between the active surface 210 and the back surface 220. In this embodiment, there is a plurality of protruding components 240 disposed on the active surface 210 of the wafer 200. The protruding components 240 are selected from bumps, solder balls, or passive components. In this embodiment, the protruding components 240 are bumps. Subsequently, referring to FIG. 3B, the wafer 200 is placed in a mold 20. The mold 20 has an upper mold 21 and a lower mold 22. A cavity 23 is formed by the upper mold 21 and the lower mold 22. The wafer 200 is placed on the lower mold 22. The active surface 210 of the wafer 200 faces the upper mold 21. In this embodiment, the width W1 of the cavity 23 is slightly greater than the diameter W2 of the wafer 200. The wafer 200 has a first height H1, and the protruding components 240 have a second height H2. Preferably, the height H3 of the cavity 23 is greater than the sum of the first height H1 and the second height H2. Thereafter, referring to FIG. 3C, a polymeric material 30 is formed in the mold 20. The polymeric material 30 may be a hot-melt material, such as a wax. The polymeric material 30 may be water insoluble or hydrophobic. The polymeric material 30 is filled in the cavity 23, and the polymeric material 30 covers at least the active surface 210 of the wafer 200. In this embodiment, the polymeric material 30 covers the side surface 230 of the wafer 200 and the polymeric material 30 encapsulates the protruding components 240. The polymeric material 30 is selected from a wax or a special glue. Thereafter, referring to FIG. 3D, the polymeric material 30 is cured and the mold 20 is removed. In this embodiment, the polymeric material 30 is a wax, which covers the active surface 210 and the side surface 230 of the wafer 200 and encapsulates the protruding components 240 to protect the wafer 200 and the protruding components 240. Alternatively, in another embodiment, the polymeric material 30 may encapsulate the back surface 220 of the wafer 200. Alternatively, referring to FIG. 4, in another embodiment, the polymeric material 30 does not completely encapsulate the side surface 230. Alternatively, referring to FIG. 5, the polymeric material 30 only encapsulates the active surface 210 of the wafer 200 and the protruding components 240 to save the time and cost of grinding. Furthermore, in various embodiments, the active surface 210 of the wafer 200 may have a plurality of recesses (not shown) formed thereon, and the polymeric material 30 may be filled in the recesses. Thereafter, referring to FIG. 3E, the wafer 200 encapsulated in the polymeric material 30 is placed on the platform 40. The active surface 210 of the wafer 200 faces the platform 40. The back surface 220 of the wafer 200 is ground by a mechanical grinding wheel 50 so as to reduce the thickness of the wafer 200. Since the polymeric material 30 covers the active surface 210 and the side surface 230 of the wafer 200 and encapsulates the protruding components 240, the side surface 230 of the wafer 200 can be protected by the polymeric material 30 during the process of grinding the back surface 200, so as to prevent the wafer from collapse in the grinding process. Furthermore, the normal pressure and lateral shear stress applied to the wafer 200 can be absorbed by the polymeric material 30 so as to prevent the wafer 200 from warpage, breakage, or collapse which may be probably produced due to non-uniform distribution of stress. Finally, the polymeric material 30 is removed to expose the active surface 210 and the protruding components 240. Water, a solvent, or a mixture thereof may be used to rinse the wafer 200 for removing the polymeric material 30. In this embodiment, the wafer 200 is rinsed by a hot water. Since the polymeric material 30 is water insoluble and selected from a wax or a special glue with a low melting point, it is easily removed and not solved in the water to contaminate the wafer 200. In the method of thinning a wafer according to the present invention, the polymeric material 30 is allowed to cover the active surface 210 and the side surface 230 of the wafer 200 and to encapsulate the protruding components 240 through a molding method utilizing the mold 20. Accordingly, the stress produced during the grinding of the wafer 200 can be uniformly distributed on the wafer 200, such that warpage, breakage, or collapse of the wafer 200 can be avoided, as well as that the peeling of the protruding components 240 can be avoided during the removal of the polymeric material.

Those skilled in the art will readily observe that numerous modifications and alterations of the device and method may be made while retaining the teachings of the invention.

What is claimed is:

1. A method of thinning a wafer, comprising:
providing a wafer having an active surface and a back surface;
placing the wafer in a cavity of a mold;
forming a polymeric material in the mold to cover at least the active surface of the wafer;
curing the polymeric material and removing the mold;
grinding the back surface of the wafer; and
removing the polymeric material.

2. The method of claim 1, wherein, the wafer having a side surface between the active surface and the back surface, and the polymeric material covers the side surface.

3. The method of claim 1, wherein the polymeric material comprises a hot-melt material.

4. The method of claim 1, wherein the polymeric material comprises a wax.

5. The method of claim 1, wherein the cavity has a width greater than a diameter of the wafer.

6. The method of claim 1, wherein the wafer comprises a plurality of protruding components disposed on the active surface of the wafer.

7. The method of claim 1, wherein the active surface of the wafer has a plurality of recesses.

8. The method of claim 6, wherein the wafer has a first height, and the protruding components have a second height.

9. The method of claim 8, wherein the height of the cavity is greater than the sum of the first height and the second height.

10. The method of claim 6, wherein the polymeric material encapsulates the protruding components.

11. The method of claim 7, wherein the polymeric material is filled in the recesses.

12. The method of claim 6, wherein the protruding components are selected from the group consisting of bumps, solder balls, and passive components.

13. The method of claim 1, wherein removing the polymeric material is performed by rinsing the wafer with water, a solvent, or a mixture thereof.

14. The method of claim 13, wherein, in the step of removing the polymeric material, the wafer is rinsed by a hot water.

15. The method of claim 1, wherein the polymeric material is water insoluble.

16. A method of thinning a wafer, comprising:
providing a wafer having an active surface, a back surface, and a side surface between the active surface and the back surface;
forming a hot-melt material to cover the active surface and the side surface of the wafer;
grinding the back surface of the wafer; and
removing the hot melt material.

17. The method of claim 16, wherein a plurality of protruding components are disposed on the active surface of the wafer.

18. The method of claim 16, wherein the active surface of the wafer has a plurality of recesses.

19. The method of claim 17, wherein the hot melt material encapsulates the protruding components.

20. The method of claim 18, wherein the hot melt material is filled in the recesses.

21. The method of claim 16, wherein, in the step of removing the hot melt material, the wafer is rinsed with a hot water.
